(19) United States
(12) Patent Application Publication
(10) Pub. No.: US 2025/0276347 A1
(43) Pub. Date: Sep. 4, 2025

(54) SUBSTRATE CLEANING APPARATUS, SUBSTRATE PROCESSING APPARATUS, SUBSTRATE CLEANING METHOD, CLEANING METHOD FOR CLEANING TOOL, A NON-TRANSITORY COMPUTER-READABLE STORAGE MEDIUM STORING, A SUBSTRATE CLEANING PROGRAM AND A NON-TRANSITORY COMPUTER-READABLE STORAGE MEDIUM STORING A CLEANING PROGRAM

(71) Applicant: EBARA CORPORATION, Tokyo (JP)

(72) Inventors: Takahiro ABE, Tokyo (JP); Mitsuru MIYAZAKI, Tokyo (JP); Hiroki MIYAMOTO, Tokyo (JP); Tatsuro SAKAI, Tokyo (JP); Shozo TAKAHASHI, Tokyo (JP)

(73) Assignee: EBARA CORPORATION, Tokyo (JP)

(21) Appl. No.: 19/069,169

(22) Filed: Mar. 3, 2025

(30) Foreign Application Priority Data
Mar. 4, 2024 (JP) 2024-031922

(51) Int. Cl. B08B 1/54; B08B 1/20; B24B 37/34; H01L 21/02; H01L 21/67

(52) U.S. Cl. CPC B08B 1/54; B08B 1/20; B24B 37/34; H01L 21/02087; H01L 21/67034

(57) ABSTRACT

Provided is a substrate cleaning apparatus including: a substrate holding and rotating mechanism that holds and rotates a substrate; a cleaning tool that cleans a bevel of the substrate; a contact detection means that detects contact between the cleaning tool and the bevel of the substrate; and a cleaning tool moving mechanism that moves the cleaning tool toward the bevel of the substrate until the contact is detected in a state where the substrate is being rotated.

### CROSS-REFERENCE TO RELATED APPLICATIONS

This application claims the benefit of Japanese Priority Patent Application JP 2024-31922 filed on Mar. 4, 2024, the entire contents of which are incorporated herein by reference.

### BACKGROUND

### Technical Field

The present invention relates to a substrate cleaning apparatus, a substrate processing apparatus, a substrate cleaning method, a cleaning method of a cleaning tool, a substrate cleaning program, and a cleaning program of a cleaning tool.

### Related Art

JP 2020-88000 A and U.S. Pat. No. 5,861,066 disclose an apparatus for cleaning a bevel (edge) of a substrate. In addition, JP 2020-150272 A discloses an apparatus that cleans (self-cleans) a substrate cleaning member itself.

### SUMMARY

By way of illustration, the following solution is provided.

[1] A substrate cleaning apparatus comprising:
a substrate holding and rotating mechanism that holds and rotates a substrate;
a cleaning tool that cleans a bevel of the substrate;
a contact detection means that detects contact between the cleaning tool and the bevel of the substrate; and
a cleaning tool moving mechanism that moves the cleaning tool toward the bevel of the substrate until the contact is detected in a state where the substrate is being rotated.
   [2] The substrate cleaning apparatus according to [1], wherein the cleaning tool moving mechanism moves the cleaning tool toward the bevel of the substrate until the contact is detected, and further moves the cleaning tool toward the substrate by a predetermined distance after the contact is detected.
   [3] The substrate cleaning apparatus according to [1] or [2], further comprising
a cleaning tool rotating mechanism that rotates the cleaning tool,
wherein the contact is detected in a state where the substrate is being rotated and the cleaning tool is not being rotated.
   [4] The substrate cleaning apparatus according to [3], wherein the contact detection means detects the contact between the cleaning tool and the bevel of the substrate based on a co-rotation of the cleaning tool due to contact between the rotating substrate and the non-rotating cleaning tool.
   [5] A substrate cleaning apparatus comprising:
a cleaning tool that cleans a substrate;
a self-cleaning member that cleans the cleaning tool;
a cleaning tool rotating mechanism that rotates the cleaning tool;
a contact detection means that detects contact between the cleaning tool and the self-cleaning member; and
a cleaning tool moving mechanism that moves the cleaning tool toward the self-cleaning member until the contact is detected in a state where the cleaning tool is being rotated.
   [6] The substrate cleaning apparatus according to [5], wherein the cleaning tool moving mechanism moves the cleaning tool toward the self-cleaning member until the contact is detected, and further moves the cleaning tool toward the self-cleaning member by a predetermined distance after the contact is detected.
   [7] The substrate cleaning apparatus according to any one of [1] to [5], wherein the contact detection means includes a torque sensor that measures a rotational torque of the cleaning tool.
   [8] The substrate cleaning apparatus according to any one of [3] to [5], wherein
the cleaning tool rotating mechanism includes a servomotor that rotates the cleaning tool, and
the contact detection means includes a torque sensor that is built into the servomotor and measures a rotational torque of the cleaning tool.
   [9] The substrate cleaning apparatus according to [7] or [8], wherein the contact detection means includes a detector that detects the contact by comparing the rotational torque measured by the torque sensor with a predetermined threshold.
   [10] A substrate processing apparatus comprising:
a substrate polishing apparatus for polishing a substrate;
the substrate cleaning apparatus according to any one of [1] to [9] for cleaning the polished substrate; and
a drying apparatus for drying the cleaned substrate.
   [11] A substrate cleaning method comprising:
a first step of moving a cleaning tool for cleaning a bevel of a substrate toward the bevel of the substrate until contact between the cleaning tool and the bevel of the substrate is detected while rotating the substrate; and
a second step of cleaning the bevel of the substrate with the cleaning tool in a state where the cleaning tool and the bevel of the substrate are in contact with each other.
   [12] The substrate cleaning method according to [11], wherein the first step includes moving the cleaning tool further toward the bevel of the substrate by a predetermined distance after the contact is detected.
   [13] A cleaning method for a cleaning tool, comprising:
a first step of moving a cleaning tool for cleaning a substrate toward a self-cleaning member while rotating the cleaning tool until contact between the cleaning tool and the self-cleaning member is detected; and
a second step of cleaning the cleaning tool in a state where the cleaning tool and the self-cleaning member are in contact with each other.
   [14] The cleaning method of a cleaning tool according to [13], wherein the first step includes moving the cleaning tool further toward the self-cleaning member by a predetermined distance after the contact is detected.
   [15] A non-transitory computer-readable storage medium storing a substrate cleaning program for causing a computer to execute a step of moving a cleaning tool for cleaning a bevel of a substrate toward the bevel of the substrate until contact between the cleaning tool and the bevel of the substrate is detected while rotating the substrate such that the cleaning tool cleans the bevel of the substrate in a state where the cleaning tool and the bevel of the substrate are in contact with each other.
   [16] A non-transitory computer-readable storage medium storing a cleaning program for a cleaning tool for causing a computer to execute a step of moving a cleaning tool for cleaning a substrate toward a self-cleaning member until contact between the cleaning tool and the self-cleaning member is detected while rotating the cleaning tool such that the cleaning tool is cleaned in a state where the cleaning tool and the self-cleaning member are in contact with each other.

### BRIEF DESCRIPTION OF DRAWINGS

FIG. 1 is a schematic configuration diagram of a substrate processing apparatus 100;

FIG. 2A is a schematic view of a substrate cleaning apparatus 4 according to a first embodiment;

FIG. 2B is a view illustrating a state in which the substrate cleaning apparatus 4 cleans a bevel of a substrate W;

FIG. 3 is a block diagram illustrating a schematic configuration of a cleaning control mechanism;

FIG. 4 is a flowchart illustrating an example of a processing operation of the cleaning control mechanism;

FIG. 5A is a schematic view illustrating temporal change of a position of a cleaning tool 12 corresponding to the processing operation illustrated in FIG. 4 and a rotational torque measured by a torque sensor 16;

FIG. 5B is a schematic view illustrating a temporal change of the position of the cleaning tool 12 corresponding to the processing operation illustrated in FIG. 4 and the rotational torque measured by the torque sensor 16;

FIG. 6A is a schematic view of a substrate cleaning apparatus 4 according to a second embodiment;

FIG. 6B is a view illustrating how a self-cleaning member 17 cleans the cleaning tool 12; and

FIG. 7 is a flowchart illustrating an example of a processing operation of the cleaning control mechanism.

### DETAILED DESCRIPTION

Hereinafter, an embodiment according to the present invention will be specifically described with reference to the drawings.

### First Embodiment

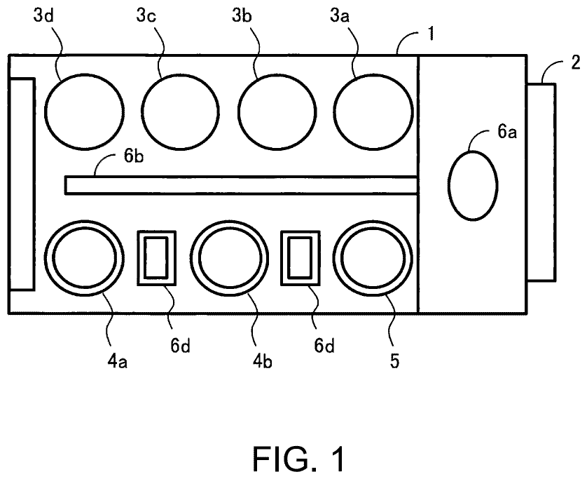

FIG. 1 is a schematic configuration diagram of a substrate processing apparatus 100. The substrate processing apparatus 100 is, for example, a CMP apparatus, and includes a substantially rectangular housing 1 and a load port 2 disposed adjacent to the housing 1.

A substrate cassette (not illustrated) for stocking a plurality of substrates W is placed on the load port 2. Examples of the substrate W include a semiconductor wafer. However, the substrate W to be processed is not limited to a semiconductor wafer, and may be another type of substrate used for manufacturing a semiconductor apparatus such as a glass substrate or a ceramic substrate. In addition, a semiconductor film, a metal film, or the like is formed on at least one surface of the substrate W.

The substrate processing apparatus 100 includes one or more (four in FIG. 1) substrate polishing apparatuses 3a to 3d (when not particularly distinguished, they may be collectively referred to as a “substrate polishing apparatus 3”), one or more (two in FIG. 1) substrate cleaning apparatuses 4a and 4b (when not particularly distinguished, they may be collectively referred to as a “substrate cleaning apparatus 4”), and one or more (one in FIG. 1) substrate drying apparatuses 5, which are disposed inside the housing 1.

As an example, the substrate polishing apparatuses 3a to 3d are disposed along one side of the housing 1 in the longitudinal direction. The substrate cleaning apparatuses 4a and 4b and the substrate drying apparatus 5 are disposed along the other side of the housing 1 in the longitudinal direction.

The substrate polishing apparatus 3 polishes the surface of the substrate W. More specifically, the substrate polishing apparatus 3 supplies slurry onto the substrate W while rotating the substrate W, and polishes the surface of the substrate W by pressing a polishing member (not illustrated) against the surface of the substrate W. Polishing waste or slurry may remain on the substrate W after polishing.

The substrate cleaning apparatus 4 cleans the surface of the substrate W after polishing. More specifically, the substrate cleaning apparatus 4 cleans the surface of the substrate W by pressing a substrate cleaning tool (not illustrated in FIG. 1) against the surface of the substrate W while rotating the substrate W. In the present embodiment, at least one substrate cleaning apparatus 4 can have a function of cleaning a bevel of a substrate. In addition, the at least one substrate cleaning apparatus 4 can have a function of cleaning the cleaning tool itself. A specific configuration example of the substrate cleaning apparatus 4 will be described below.

The substrate drying apparatus 5 dries the surface of the substrate W after cleaning. For example, the substrate drying apparatus 5 is a spin drying device, and while ejecting isopropyl alcohol vapor from an injection nozzle to the rotating substrate W to dry the substrate W, the substrate W is rotated at a high speed to dry the substrate W by a centrifugal force.

In addition, the substrate processing apparatus 100 includes substrate transport apparatuses 6a to 6d (when not particularly distinguished, they may be collectively referred to as a “substrate transport apparatus 6”), which are disposed inside the housing 1.

The substrate transport apparatus 6a is disposed adjacent to the load port 2. The substrate transport apparatus 6a receives the substrate W before treatment from the load port 2 and transports the substrate W to the substrate transport apparatus 6b, and receives the substrate W after treatment from the substrate transport apparatus 6b.

The substrate transport apparatus 6b extends in the longitudinal direction at the central portion of the housing 1. The substrate transport apparatus 6b receives the substrate W before treatment from the substrate transport apparatus 6a and transports the substrate W to any one of the substrate polishing apparatuses 3a to 3d, receives the substrate W after polishing from the substrate polishing apparatuses 3a to 3d and transports the substrate W to the substrate transport apparatus 6c, or receives the substrate W after drying from the substrate transport apparatus 6d and transports the substrate W to the substrate transport apparatus 6a.

The substrate transport apparatus 6c is disposed between the substrate cleaning apparatuses 4a and 4b. The substrate transport apparatus 6c receives the substrate W after polishing from the substrate transport apparatus 6b and transports the substrate W to either the substrate cleaning apparatus 4a or 4b, or receives the substrate W after cleaning from the substrate cleaning apparatus 4a and transports the substrate W to the substrate cleaning apparatus 4b.

The substrate transport apparatus 6d is disposed between the substrate cleaning apparatus 4b and the substrate drying apparatus 5. The substrate transport apparatus 6d receives the substrate W after cleaning from the substrate cleaning apparatus 4b and transports the substrate W to the substrate drying apparatus 5, or receives the substrate W after drying from the substrate drying apparatus 5 and transports the substrate W to the substrate transport apparatus 6b.

Note that the arrangement of the substrate polishing apparatus 3, the substrate cleaning apparatus 4, the substrate drying apparatus 5, and the substrate transport apparatus 6 is merely an example. One or more substrate transport apparatuses 6 may be provided so that the substrate W can be transported in the order of the substrate polishing apparatus 3, the substrate cleaning apparatus 4, and the substrate drying apparatus 5.

The present embodiment makes it possible to appropriately clean the bevel of the substrate W in the substrate cleaning apparatus 4 having a function of cleaning the bevel of the substrate W.

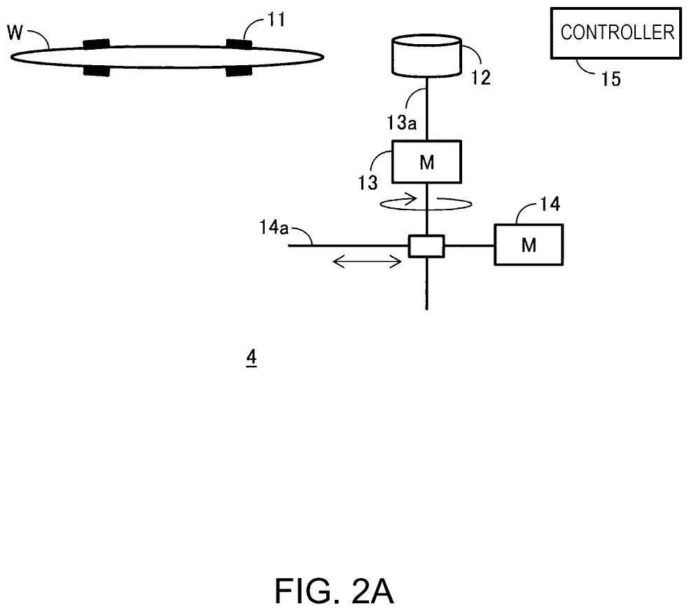

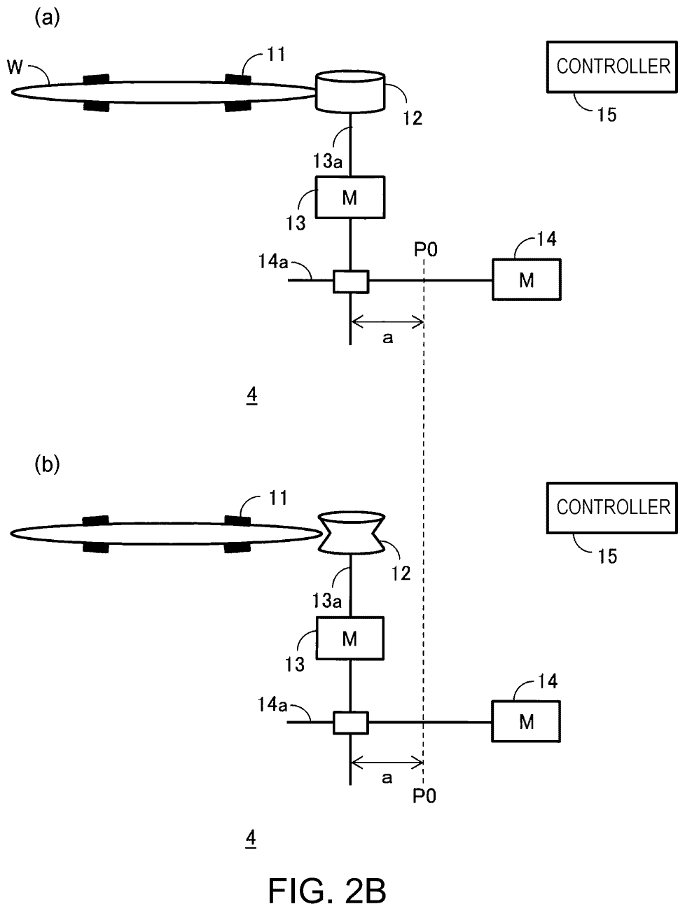

FIG. 2A is a schematic view of the substrate cleaning apparatus 4 according to the first embodiment. The substrate cleaning apparatus 4 includes a roller 11 (substrate holding and rotating mechanism), a cleaning tool 12, a rotary motor 13 (cleaning tool rotating mechanism), a moving motor 14 (cleaning tool moving mechanism), and a controller 15.

The roller 11 holds and rotates the substrate W. As a specific example, a groove (recess) is formed in the roller 11, and the edge of the substrate W is sandwiched by the groove to hold the substrate W in the horizontal direction. Then, the roller 11 is driven by a motor (not illustrated) to rotate, and the held substrate W rotates in a horizontal plane. The roller 11 may hold and rotate the substrate W in the vertical direction. The groove of the roller 11 may become worn due to use, whereby the position where the substrate W is held may vary.

The cleaning tool 12 is configured to clean the bevel of the substrate W. As a specific example, the cleaning tool 12 is a cylindrical PVA sponge, and the side surface thereof comes into contact with the bevel of the substrate W to clean the substrate W. The cleaning tool 12 (particularly, a position in contact with the bevel of the substrate W) may become worn due to use.

The rotary motor 13 rotates the cleaning tool 12 about the rotating shaft 13a. As a specific example, the rotating shaft 13a to which the cleaning tool 12 is fixed at the tip extends in the vertical direction (direction orthogonal to the direction in which the substrate W is held), and the rotary motor 13 rotates the cleaning tool 12 in the horizontal plane.

The moving motor 14 moves the cleaning tool 12 toward the substrate W. As a specific example, a pressing shaft 14a extending in the horizontal direction (direction in which the substrate W is held) is provided. The moving motor 14 moves the rotating shaft 13a and the cleaning tool 12 in the horizontal direction along the pressing shaft 14a.

The controller 15 controls the rotary motor 13 and the moving motor 14. Although details thereof will be described below, some or all of the functions of the controller 15 may be realized by a processor executing a program.

FIG. 2B is a view illustrating how the substrate cleaning apparatus 4 cleans the bevel of the substrate W. (a) of FIG. 2B illustrates a case where the cleaning tool 12 is not worn, and (b) of FIG. 2B illustrates a case where the cleaning tool 12 is worn.

As illustrated in (a) of FIG. 2B, the moving motor 14 moves the cleaning tool 12 toward the substrate W by a distance a from a predetermined reference position P0 (initial position), whereby the side surface of the cleaning tool 12 comes into contact with the bevel of the substrate W. In this state, the roller 11 rotates the substrate W, and the rotary motor 13 rotates the cleaning tool 12, so that the bevel of the substrate W is cleaned. Although not illustrated, a cleaning liquid (pure water or a chemical solution) may be supplied to the substrate W at the time of cleaning.

Here, as illustrated in (b) of FIG. 2B, in a case where the cleaning tool 12 is worn, the side surface of the cleaning tool 12 does not sufficiently come into contact with the bevel of the substrate W even if the cleaning tool 12 is moved toward the substrate W by the same distance a. As a result, the bevel of the substrate W may not be properly cleaned. The same may occur in a case where the positional relationship between the substrate W and the cleaning tool 12 is not constant, such as a case where the position where the substrate W is held changes due to wear of the roller 11 or a case where the shape of the cleaning tool 12 varies individually.

Therefore, in the present embodiment, the substrate cleaning apparatus 4 includes the following cleaning control mechanism.

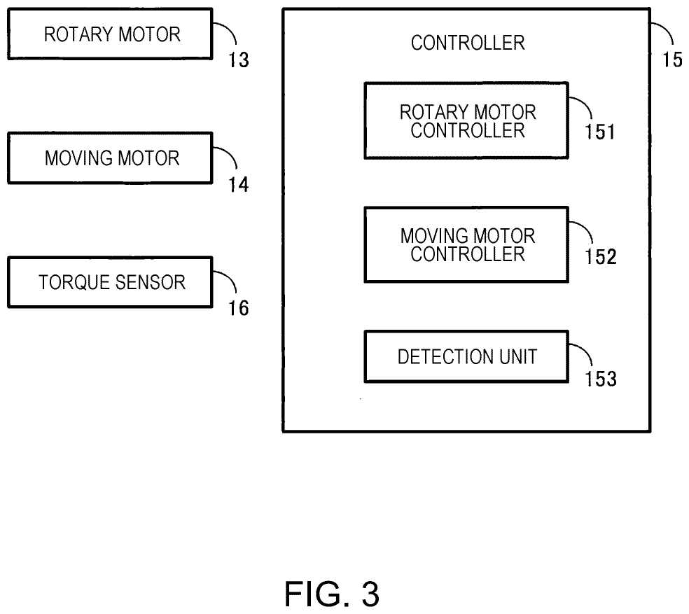

FIG. 3 is a block diagram illustrating a schematic configuration of a cleaning control mechanism. The cleaning control mechanism can include the rotary motor 13, the moving motor 14, and the controller 15 illustrated in FIG. 2A, and a torque sensor 16. The controller 15 includes a rotary motor controller 151, a moving motor controller 152, and a detector 153.

The torque sensor 16 measures the rotational torque of the cleaning tool 12 and transmits the measurement result to the controller 15. As a specific configuration example, the rotary motor 13 is a servomotor, and the torque sensor 16 may be built into the servomotor. Since a current flows through the rotary motor 13 as the cleaning tool 12 rotates, the torque sensor 16 can measure the rotational torque of the cleaning tool 12 based on the amount of the current.

The rotary motor controller 151 is connected to the rotary motor 13, and controls the rotary motor 13 by transmitting a predetermined signal. The moving motor controller 152 is connected to the moving motor 14, and controls the moving motor 14 by transmitting a predetermined signal.

The detector 153 detects contact between the cleaning tool 12 and the substrate W based on the measurement result of the torque sensor 16. As a specific example, by using the fact that the rotational torque increases when the cleaning tool 12 comes into contact with the substrate W and comparing the measured rotational torque with a threshold, the detector 153 can detect that the cleaning tool 12 has come into contact with the substrate W.

Note that the torque sensor 16 and the detector 153 described above are merely examples of contact detection means, and the contact between the cleaning tool 12 and the substrate W may be detected by other methods.

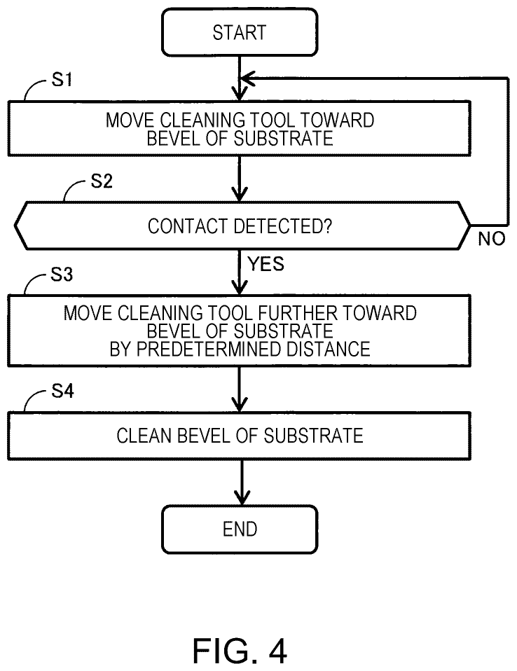

FIG. 4 is a flowchart illustrating an example of a processing operation of the cleaning control mechanism. Based on the control of the moving motor controller 152, the moving motor 14 moves the cleaning tool 12 toward the bevel of the substrate W (step S1). Then, when the detector 153 detects the contact between the cleaning tool 12 and the substrate W (YES in step S2), the moving motor 14 further moves the cleaning tool 12 toward the bevel of the substrate W by a predetermined distance do (step S3). Then, the bevel of the substrate W is cleaned by rotating the cleaning tool 12 and the substrate W in a state where the cleaning tool 12 and the substrate W are in contact with each other (step S4).

The predetermined distance do may be appropriately determined in consideration of the material of the cleaning tool 12, the required pressing force, and the like, and may be, for example, about one to several millimeters, or may be 0 millimeters in some cases (that is, step S3 may be omitted).

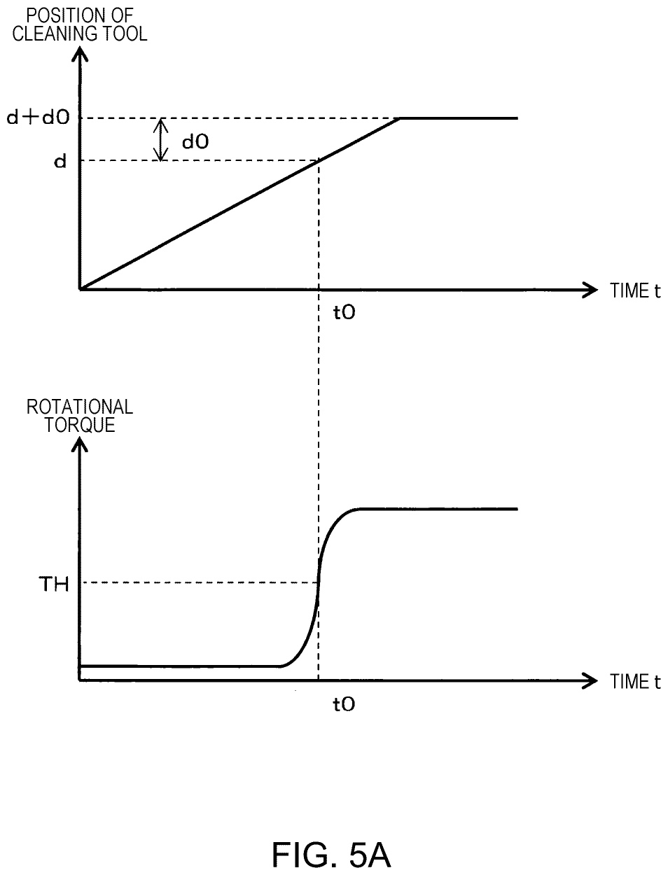

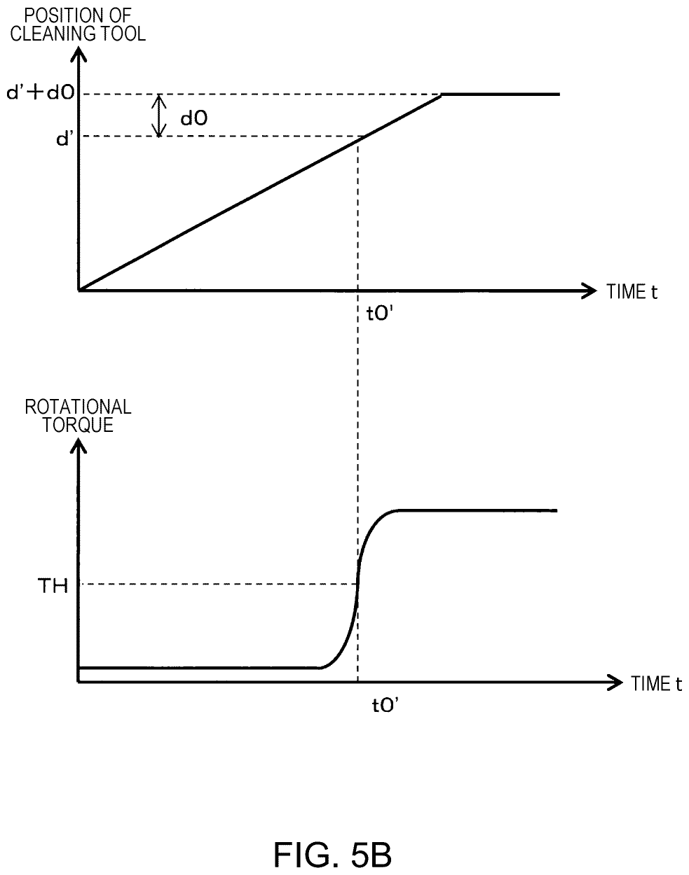

FIG. 5A is a schematic diagram illustrating the temporal change of the position of the cleaning tool 12 corresponding to the processing operation illustrated in FIG. 4 and the rotational torque measured by the torque sensor 16, and assumes a case where the cleaning tool 12 is not worn ((a) of FIG. 2B).

The cleaning tool 12 approaches the substrate W with the lapse of time, and the measured rotational torque exceeds a threshold TH at a certain time to. In response to this, the detector 153 detects that the cleaning tool 12 has come into contact with the substrate W (step S2 in FIG. 4). A distance d (distance from the reference position P0) by which the cleaning tool 12 has moved until the time to naturally depends on the time to until the contact is detected.

Thereafter, the bevel is cleaned in a state where the cleaning tool 12 moves by a predetermined distance do (step S3 in FIG. 4) and the cleaning tool 12 moves by a distance d+d0 from the reference position P0.

FIG. 5B is a schematic diagram illustrating the temporal change of the position of the cleaning tool 12 corresponding to the processing operation illustrated in FIG. 4 and the rotational torque measured by the torque sensor 16, and assumes a case where the cleaning tool 12 is worn ((b) of FIG. 2B).

The cleaning tool 12 approaches the substrate W with the lapse of time, and the measured rotational torque exceeds the threshold TH at a certain time to′. In response to this, the detector 153 detects that the cleaning tool 12 has come into contact with the substrate W (step S2 in FIG. 4). Since the cleaning tool 12 is worn, a distance d′ (distance from the reference position P0) by which the cleaning tool 12 has moved by the time to′ is longer than the distance d illustrated in FIG. 5A.

Thereafter, the bevel is cleaned in a state where the cleaning tool 12 moves by a predetermined distance d0 (step S3 in FIG. 4) and the cleaning tool 12 moves by a distance d′+d0 from the reference position P0.

Note that while the roller 11 rotates the substrate W until the cleaning tool 12 is moved toward the substrate W and the contact is detected (step S1 in FIG. 4), it is desirable that the rotary motor 13 does not rotate the cleaning tool 12. In other words, the contact detection is desirably performed in a state where the substrate W is rotated and the cleaning tool 12 is not rotated.

In this way, the rotating substrate W and the non-rotating cleaning tool 12 come into contact with each other, and the cleaning tool 12 rotates together. That is, the cleaning tool 12 rotates so as to be pulled and dragged along the rotating substrate W, whereby the rotary motor 13 is rotated. Therefore, the rotational torque greatly changes due to the start of the corotation, and the contact can be accurately detected.

Note that the distances d and d′ at which the contact has been detected may be stored, and the wear amount of the cleaning tool 12 may be estimated or the replacement time of the cleaning tool 12 may be predicted.

As described above, in the present embodiment, the distance for moving the cleaning tool 12 is not a fixed value, but a value corresponding to the distance until the contact between the cleaning tool 12 and the substrate W is detected. Therefore, even when the positional relationship between the substrate W and the cleaning tool 12 is not constant due to wear or the like of the cleaning tool 12, the cleaning tool 12 can be reliably brought into contact with the bevel of the substrate W, and the bevel of the substrate W can be appropriately cleaned.

### Second Embodiment

In a second embodiment described below, the cleaning tool 12 can be appropriately cleaned in the substrate cleaning apparatus 4 including a self-cleaning member that cleans the cleaning tool 12. Hereinafter, common points with the first embodiment will be omitted or simplified.

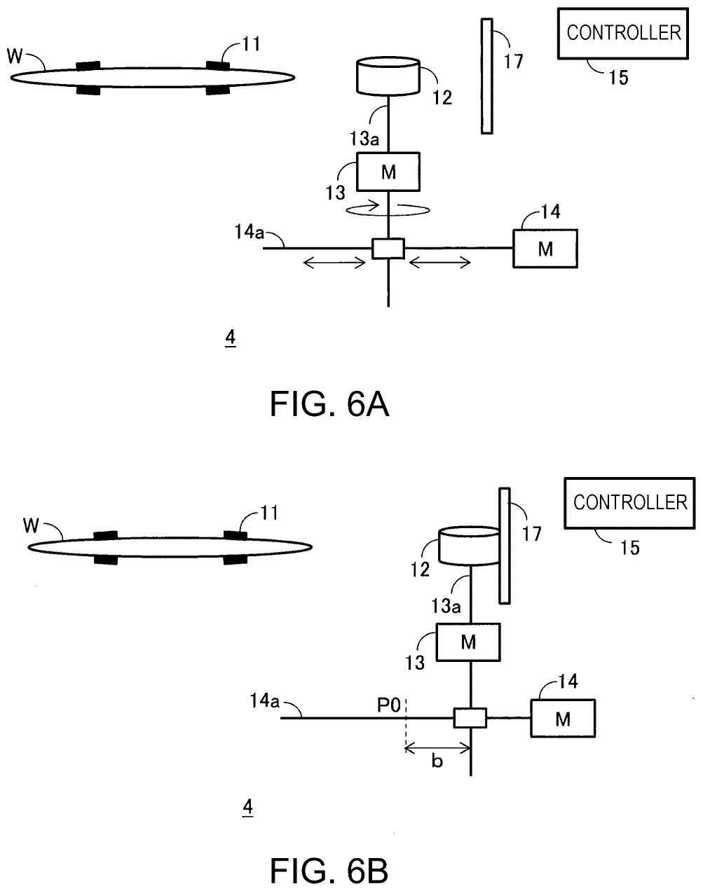

FIG. 6A is a schematic view of the substrate cleaning apparatus 4 according to the second embodiment. The substrate cleaning apparatus 4 includes a self-cleaning member 17. The self-cleaning member 17 is made of, for example, quartz and has a plate shape. In addition, the moving motor 14 of the present embodiment moves the cleaning tool 12 toward the self-cleaning member 17. As a specific example, the pressing shaft 14a extends in the horizontal direction (direction in which the substrate W is held), the substrate W is provided on one side (left side in the drawing), and the self-cleaning member 17 is provided on the other side (right side in the drawing). The moving motor 14 moves the rotating shaft 13a and the cleaning tool 12 in the horizontal direction along the pressing shaft 14a.

FIG. 6B is a view illustrating how the self-cleaning member 17 cleans the cleaning tool 12. When the moving motor 14 moves the cleaning tool 12 toward the self-cleaning member 17 by a distance b from the predetermined reference position P0 (initial position), the side surface of the cleaning tool 12 comes into contact with the self-cleaning member 17. In this state, when the rotary motor 13 rotates the cleaning tool 12, the cleaning tool 12 is pressed against the self-cleaning member 17, and the cleaning tool 12 is cleaned. Although not illustrated, a cleaning liquid (pure water or chemical liquid) may be supplied to the substrate W and the self-cleaning member 17 at the time of cleaning.

Similarly to the first embodiment, when the cleaning tool 12 is worn, even if the cleaning tool 12 is moved toward the self-cleaning member 17 by the distance b, the side surface of the cleaning tool 12 does not sufficiently contact the self-cleaning member 17. Therefore, also in the present embodiment, the cleaning control mechanism illustrated in FIG. 3 is provided.

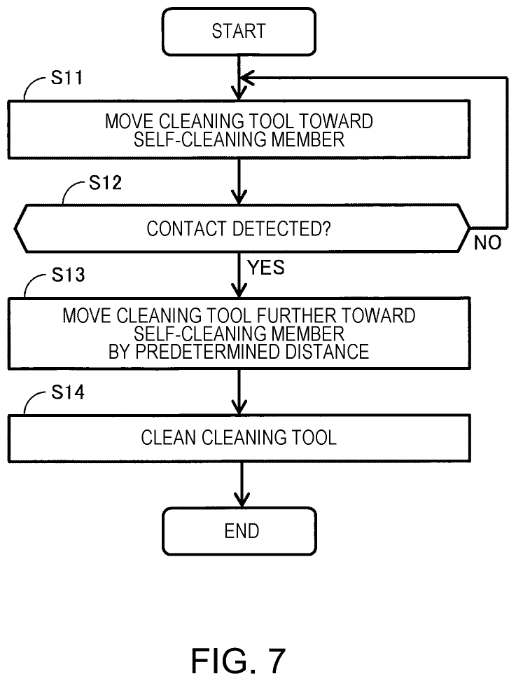

FIG. 7 is a flowchart illustrating an example of a processing operation of the cleaning control mechanism. Based on the control of the moving motor controller 152, the moving motor 14 moves the cleaning tool 12 toward the self-cleaning member 17 (step S11). Then, when the detector 153 detects the contact between the cleaning tool 12 and the self-cleaning member 17 (YES in step S12), the moving motor 14 further moves the cleaning tool 12 toward the self-cleaning member 17 by a predetermined distance d1 (step S13). Then, the cleaning tool 12 is cleaned by rotating the cleaning tool 12 in a state where the cleaning tool 12 and the self-cleaning member 17 are in contact with each other (step S14).

The predetermined distance d1 may be appropriately determined in consideration of the material of the cleaning tool 12, the material of the self-cleaning member 17, the required pressing force, and the like, and may be, for example, about one to several millimeters, or may be 0 millimeters in some cases (that is, step S13 may be omitted).

When the self-cleaning member 17 does not rotate, the cleaning tool 12 is moved toward the self-cleaning member 17, and the rotary motor 13 rotates the cleaning tool 12 until the contact is detected (step S11 in FIG. 7). In other words, the contact detection is performed in a state where the cleaning tool 12 is being rotated. As a result, even if the self-cleaning member 17 does not rotate, the detector 153 can detect the contact between the cleaning tool 12 and the self-cleaning member 17 using the torque sensor 16.

As described above, in the present embodiment, the distance for moving the cleaning tool 12 is not a fixed value, but a value corresponding to the distance until the contact between the cleaning tool 12 and the self-cleaning member 17 is detected. Therefore, even when the positional relationship between the substrate W and the self-cleaning member 17 is not constant due to wear or the like of the cleaning tool 12, the cleaning tool 12 can be reliably brought into contact with the self-cleaning member 17, and the cleaning tool 12 can be appropriately cleaned.

Note that the present embodiment is not limited to the substrate cleaning apparatus 4 that cleans the bevel of the substrate W, and can be applied to any substrate cleaning apparatus. That is, the cleaning tool 12 may be any substrate cleaning tool, and may be, for example, a roll type or a pencil type that cleans the surface of the substrate W.

Any part or all of the functional units described in the present specification may be realized by a program. The program mentioned in the present specification may be non-transiently recorded in a computer-readable recording medium.

Such a program may be installed on a computer (so-called native application). In this case, the program may be downloaded to the computer via a communication line (including wireless communication) such as the Internet, or may be distributed in a state of being installed in the computer.

Based on the above description, a person skilled in the art may be able to conceive additional effects and various modifications of the present invention, but aspects of the present invention are not limited to the individual embodiments described above. For example, an invention in which only a part of each embodiment is extracted or an invention in which a plurality of embodiments are combined is naturally assumed. Various additions, modifications, and partial deletions can be made without departing from the conceptual idea and spirit of the present invention derived from the contents defined in the claims and equivalents thereof.

For example, what is described herein as a single device (or member, the same applies hereinafter) (including what is depicted in the drawings as a single device) may be implemented by a plurality of devices. Conversely, what is described herein as a plurality of devices (including what is depicted in the drawings as a plurality of devices) may be realized by one device. Alternatively, some or all of the means and functions included in a certain device may be included in another device.

In addition, not all the matters described in the present specification are essential requirements. In particular, matters described in the present specification and not described in the claims can be regarded as any additional matters.

In addition, the term “means” in the present specification and claims means hardware (or a function implemented by hardware) itself and does not include a human (or mental activity of a human) unless otherwise specified.

It should be noted that the applicant of the present invention is merely aware of the invention disclosed in the document in the column of “Prior Art Document” in the present specification, and the present invention is not necessarily intended to solve the problem in the invention disclosed in the document. The problem to be solved by the present invention should be recognized in consideration of the entire specification. For example, in the present specification, in a case where there is a description that a predetermined effect is exhibited by a specific configuration, it can be said that the problem of reversing the predetermined effect is solved. However, such a specific configuration is not necessarily an essential requirement.

### REFERENCE SIGNS LIST

1 Substrate processing apparatus
2 Load port
3, 3a to 3d Substrate polishing apparatus
4, 4a, 4b Substrate cleaning apparatus
5 Substrate drying apparatus
6, 6a to 6d Substrate transport apparatus
11 Roller
12 Cleaning tool
13 Rotary motor
13a Rotating shaft
14 Moving motor
14a Pressing shaft
15 Controller
151 Rotary motor controller
152 Moving motor controller
153 Detector
16 Torque sensor
17 Self-cleaning member

What is claimed is:

1. A substrate cleaning apparatus comprising:
a substrate holding and rotating mechanism that holds and rotates a substrate;
a cleaning tool that cleans a bevel of the substrate;
a contact detection means that detects contact between the cleaning tool and the bevel of the substrate; and
a cleaning tool moving mechanism that moves the cleaning tool toward the bevel of the substrate until the contact is detected in a state where the substrate is being rotated.

2. The substrate cleaning apparatus according to claim 1, wherein the cleaning tool moving mechanism moves the cleaning tool toward the bevel of the substrate until the contact is detected, and further moves the cleaning tool toward the substrate by a first distance after the contact is detected.

3. The substrate cleaning apparatus according to claim 1, further comprising
a cleaning tool rotating mechanism that rotates the cleaning tool,
wherein the contact is detected in a state where the substrate is being rotated and the cleaning tool is not being rotated.

4. The substrate cleaning apparatus according to claim 3, wherein the contact detection means detects the contact between the cleaning tool and the bevel of the substrate based on a co-rotation of the cleaning tool due to contact between the rotating substrate and the non-rotating cleaning tool.

5. A substrate cleaning apparatus comprising:
a cleaning tool that cleans a substrate;
a self-cleaning member that cleans the cleaning tool;
a cleaning tool rotating mechanism that rotates the cleaning tool;
a contact detection means that detects contact between the cleaning tool and the self-cleaning member; and
a cleaning tool moving mechanism that moves the cleaning tool toward the self-cleaning member until the contact is detected in a state where the cleaning tool is being rotated.

6. The substrate cleaning apparatus according to claim 5, wherein the cleaning tool moving mechanism moves the cleaning tool toward the self-cleaning member until the contact is detected, and further moves the cleaning tool toward the self-cleaning member by a first distance after the contact is detected.

7. The substrate cleaning apparatus according to claim 1, wherein the contact detection means includes a torque sensor that measures a rotational torque of the cleaning tool.

8. The substrate cleaning apparatus according to claim 3, wherein
the cleaning tool rotating mechanism includes a servomotor that rotates the cleaning tool, and
the contact detection means includes a torque sensor that is built into the servomotor and measures a rotational torque of the cleaning tool.

9. The substrate cleaning apparatus according to claim 7, wherein the contact detection means includes a detector that detects the contact by comparing the rotational torque measured by the torque sensor with a first threshold.

10. A substrate processing apparatus comprising:
a substrate polishing apparatus for polishing a substrate;
the substrate cleaning apparatus according to claim 1 for cleaning the polished substrate; and
a drying apparatus for drying the cleaned substrate.

11. A substrate cleaning method comprising:
a first step of moving a cleaning tool for cleaning a bevel of a substrate toward the bevel of the substrate until contact between the cleaning tool and the bevel of the substrate is detected while rotating the substrate; and
a second step of cleaning the bevel of the substrate with the cleaning tool in a state where the cleaning tool and the bevel of the substrate are in contact with each other.

12. The substrate cleaning method according to claim 11, wherein the first step includes moving the cleaning tool further toward the bevel of the substrate by a first distance after the contact is detected.

13. A cleaning method for a cleaning tool, comprising:
a first step of moving a cleaning tool for cleaning a substrate toward a self-cleaning member while rotating the cleaning tool until contact between the cleaning tool and the self-cleaning member is detected; and
a second step of cleaning the cleaning tool in a state where the cleaning tool and the self-cleaning member are in contact with each other.

14. The cleaning method of a cleaning tool according to claim 13, wherein the first step includes moving the cleaning tool further toward the self-cleaning member by a first distance after the contact is detected.

15. A non-transitory computer-readable storage medium storing a substrate cleaning program for causing a computer to execute a step of moving a cleaning tool for cleaning a bevel of a substrate toward the bevel of the substrate until contact between the cleaning tool and the bevel of the substrate is detected while rotating the substrate such that the cleaning tool cleans the bevel of the substrate in a state where the cleaning tool and the bevel of the substrate are in contact with each other.

16. A non-transitory computer-readable storage medium storing a substrate cleaning program for a cleaning tool for causing a computer to execute a step of moving a cleaning tool for cleaning a substrate toward a self-cleaning member until contact between the cleaning tool and the self-cleaning member is detected while rotating the cleaning tool such that the cleaning tool is cleaned in a state where the cleaning tool and the self-cleaning member are in contact with each other.
